(19) United States
(12) Patent Application Publication
(10) Pub. No.: US 2008/0048224 A1
(43) Pub. Date: Feb. 28, 2008

(54) FABRICATING CMOS IMAGE SENSOR

(76) Inventor: In-Guen Yeo, Gwangju (KR)

Correspondence Address: SHERR & NOURSE, PLLC, 620 HERNDON PARKWAY, SUITE 200, HERNDON, VA, 20170, US

(21) Appl. No.: 11/844,718

(22) Filed: Aug. 24, 2007

(30) Foreign Application Priority Data
Aug. 28, 2006 (KR) 10-2006-0081960

(51) Int. Cl. H01L 31/062; H01L 21/00

(52) U.S. Cl. 257/292; 438/70; 257/E31.001

(57) ABSTRACT

A CMOS image sensor includes at least one of: A P-type semiconductor substrate. A P-type photodiode formed in the P-type semiconductor substrate and having a higher impurity concentration than the semiconductor substrate. An N-type photodiode disposed over the P-type photodiode at a depth less than approximately 0.15 μm from the surface of the semiconductor substrate. A depletion layer provided by junction of the P-type photodiode and the N-type photodiode.

The present application claims priority under 35 U.S.C. 119 to Korean Patent Application No. 10-2006-0081960 (filed on Aug. 28, 2006), which is hereby incorporated by reference in its entirety.

### BACKGROUND

Image sensors may be used for different applications (e.g. machine vision, robots, satellite-related systems, vehicles, navigation, guidance, etc). Image sensors may include a plurality of pixels arranged in a two-dimension array to form an image frame. In image sensors, light energy reflected from an object may be absorbed by a photoelectric conversion unit and electrons may be emitted as a result of a photoelectric effect. The emission of electrons may be proportional to the quantity of light absorbed. The emitted electrons may be accumulated in a photoelectric conversion unit (e.g. formed in a semiconductor substrate) and may then be read out of the photoelectric conversion unit in a read-out operation. Photodiodes may be used as a photoelectric conversion unit.

A color image sensor may use color filters to filter light having specific wavelengths. For example, a red color filter, a green color filter, and a blue color filter may be used in an image sensor for the three primary colors (i.e. red (R), green (G), and blue (B)). Different color filters may have different transmission and absorption characteristics at specific wavelengths, so that only light of a predetermined wavelength range may pass through a color filter and be received at an underlying photodiode. The transmitted light (i.e. the light passed through the color filter) at the specific wavelengths may generates electrons in a depletion region in the underlying photodiode. By arranging an array of photodiodes with a combination of different color filters, an image sensor may detect electrons from the photodiodes to recognize a color ratio.

To measure color ratios of the three primary colors, a color image sensor may include a red color filter, a green color filter, and a blue color filter. Each of these different types of color filters, may need to be formed by different exposure processes and etching processes. Accordingly, processing time of an image sensor may be relatively long due to the formation of the color filters and loss of blue light may be caused by the color filters.

### SUMMARY

Embodiments relates to a complementary meal oxide semiconductor (CMOS) image sensor, which may maximize sensitivity to blue light and maximize manufacturing yield. Embodiments relates to a method of manufacturing a complementary meal oxide semiconductor (CMOS) image sensor, which may maximize sensitivity to blue light and maximize manufacturing yield. In embodiments, a CMOS image sensor may not need a blue color filter.

In embodiments, a CMOS image sensor includes at least one of: A P-type semiconductor substrate. A P-type photodiode formed in the P-type semiconductor substrate and having a higher impurity concentration than the semiconductor substrate. An N-type photodiode disposed over the P-type photodiode at a depth less than approximately 0.15 μm from the surface of the semiconductor substrate. A depletion layer provided by junction of the P-type photodiode and the N-type photodiode.

In embodiments, a method for manufacturing a CMOS image sensor includes at least one of the following steps: Preparing a P-type semiconductor substrate. Implanting a P-type impurity, having a concentration which is higher than the P-type semiconductor substrate, into the P-type semiconductor substrate to form a P-type photodiode. Implanting a N-type impurity into the P-type photodiode to form an N-type photodiode, with the N-type photodiode being above the P-type photodiode at a depth less than approximately 0.15 μm from the surface of the P-type semiconductor substrate. Forming a depletion layer by junction of the P-type photodiode and the N-type photodiode.

### DRAWINGS

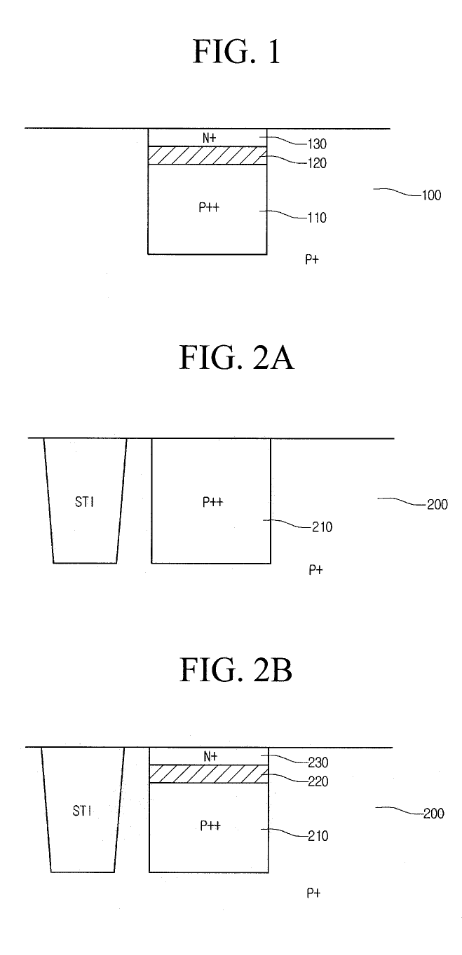

Example FIG. 1 illustrates a CMOS image, according to embodiments.

Example FIGS. 2A and 2B illustrate a method of manufacturing a CMOS image sensor, according to embodiments.

### DESCRIPTION

FIG. 1 is a cross-sectional view of a CMOS image sensor when a bias voltage is applied, in accordance with embodiments. A CMOS image sensor may include a semiconductor substrate 100 having a pixel region in an area where a P-type impurity is implanted. A CMOS image sensor may include a P-type photodiode 110 and an N-type photodiode 130. A P-type photodiode 110 may be formed within the semiconductor substrate 100 having a higher P-type (P++) impurity concentration than the semiconductor substrate 100. An N-type photodiode 130 may be formed over the P-type photodiode 110. The P++ impurity for the P-type photodiode 110 may include boron (B) and/or BF4, in accordance with embodiments. In embodiments, an N-type photodiode may be formed by implanting phosphorus ions.

When a bias voltage is applied to a CMOS image sensor, a depletion region 120 corresponding to a boundary between P-type photodiode 110 and N-type photodiode 230 may be present. In embodiments, the depth of depletion region 120 when a bias voltage is applied may be based the thickness of N-type photodiode 110. In embodiments, N-type photodiode 110 may be formed at a depth of approximately 0.15 μm below the surface of semiconductor substrate 100. However, one of ordinary skill will appreciate other depths, in accordance with embodiments.

At an initial stage, P-type photodiode 110 and N-type photodiode 130 may have depletion-like characteristic due to lost electrons from an operation of a reset transistor that removes electrons from the diode, in accordance with embodiments. Accordingly, at an initial stage of an image sensor, N-type photodiode 130 may exhibit a photoelectric response by silicon atoms to blue light.

Example Table 1 illustrates the relationship between wavelength and depth of half absorption for colors.

TABLE 1

| | Wavelength | Depth of half absorption |
|---|---|---|
| Color | (nm) | (μm) |
| Violet | 400 | 0.093 |
| Green | 530 | 0.790 |
| Yellow | 600 | 1.200 |
| Red | 700 | 3.000 |

As illustrated in example Table 1, unlike red light and green light, blue light causes the photoelectric effect by response of the depletion layer near the surface of the semiconductor substrate 100 and does not penetrate the photodiode, in accordance with embodiments. Accordingly, sensitivity to blue light may be relatively low compared to red light and the green light.

In embodiments, the depletion layer responsive to the blue light may be formed near the surface of semiconductor substrate 100. In embodiments, a depletion layer may be formed at a depth between approximately 0.1 μm and approximately 0.2 μm from the surface of semiconductor substrate 100. In other words, if depletion layer 120 is formed at a depth more than 0.2 μm from the surface of semiconductor substrate 100 when a bias voltage is applied, it may be difficult for the depletion layer 120 to respond to blue light. If the depletion layer 120 is formed at a depth less than 0.1 μm, the depletion layer 120 may responds to light having a wavelength shorter than blue light. In other words, the sensitivity of an image sensor to blue light may be relatively low.

In embodiments, depletion layer 120 may be formed at a depth between approximately 0.1 μm and approximately 0.2 μm, so that an image sensor may respond to blue light to generate electrons. Accordingly, a color filter for detecting only blue light may not be unnecessary, in accordance with embodiments.

Example FIGS. 2A and 2B are cross-sectional views illustrating a method of manufacturing an image sensor, in accordance with embodiments. A pixel region may be defined in semiconductor substrate 200 by a shallow trench isolation (STI) layer. A P-type impurity may be implanted into the pixel region. A P-type photodiode 210 may be formed in semiconductor substrate 200 by implanting P-type impurity having a higher concentration (P++) than the semiconductor substrate 200. As illustrated in example FIG. 2A, a lower structure 210 of the photodiode may be exposed at the surface of the semiconductor substrate 200. In embodiments, a P++impurity for a P-type photodiode 210 may include boron (B) or BF4.

As illustrated in example FIG. 2B, an N-type photodiode 230 may be formed by implanting N-type impurity into the semiconductor substrate over the lower structure 210 of the photodiode, in accordance with embodiments. In embodiments, the N-type impurity may include phosphorus.

In embodiments, N-type impurity may be implanted by adjusting an ion implantation energy such that an N-type photodiode 230 is formed with a depth of approximately 0.15 μm from the surface of the semiconductor substrate 200. However, one of ordinary skill will appreciate other depths. Different ion implantation energies may be used for forming the N-type photodiode 230 at an appropriate depth based on the kind of the N-type impurity used, in accordance with embodiments.

In embodiments, depletion layer 220 may be formed by the junction of the P-type photodiode 210 and the N-type photodiode 230 formed at a depth between approximately 0.1 μm and approximately 0.2 μm. In embodiments, if the depletion layer 220 formed in the N-type photodiode 230 is formed at a depth more than 0.2 μm when a bias voltage is applied, it may be difficult for the depletion layer 220 to respond to blue light. In embodiments, if the depletion layer 220 is formed at a depth of less than approximately 0.1 μm, the depletion layer 220 may responds to light having a wavelength less than the blue light, which may cause sensitivity to blue light to be relatively low. However, in accordance with embodiments, other depths may be appreciated for depletion layer 220.

In accordance with embodiments, a depletion layer may be formed at a relatively low depth (e.g. a depth between approximately 0.1 μm and approximately 0.2 μm) from the surface of a semiconductor substrate, so that electrons may be generated by a photoelectric response to the blue light without the need for blue color filters. If a CMOS image sensor does not need separate color filters for the blue light, the process of forming the color filter for blue light may be eliminated from a manufacturing process. By a manufacturing process not needed to form blue color filters, manufacturing processing time and/or resources may be minimized, in accordance with embodiments. In embodiments, since no blue light is lost by a color filter, the sensitivity of the image sensor may be maximized.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
a P-type semiconductor substrate;
a P-type photodiode formed in the P-type semiconductor substrate; and
an N-type photodiode formed in the P-type semiconductor substrate over the P-type photodiode, wherein:
the junction of the P-type photodiode and the N-type photodiode form a depletion region, and
a depth of the depletion region configures the N-type photodiode to have a photoelectric effect in response to blue light.

2. The apparatus of claim 1, wherein the apparatus is a CMOS image sensor.

3. The apparatus of claim 1, wherein the P-type photodiode has a higher impurity concentration than the P-type semiconductor substrate.

4. The apparatus of claim 1, wherein the depth of the depletion region substantially prevents a photoelectric effect in response to light having a wavelength greater than the wavelength of blue light.

5. The apparatus of claim 1, wherein the depth of the depletion region is based on a depth of the N-type photodiode.

6. The apparatus of claim 5, wherein the depth of the N-type photodiode is between approximately 0.1 μm and approximately 0.2 μm from the surface of the semiconductor substrate.

7. The apparatus of claim 6, wherein the depth of the N-type photodiode is approximately 0.15 μm from the surface of the semiconductor substrate.

8. The apparatus of claim 1, wherein the P-type photodiode is formed by implanting at least one of boron ions and BF4 ions.

9. The apparatus claim 1, wherein the N-type photodiode is formed by implanting phosphorus ions.

10. The apparatus of claim 1, wherein the depletion region is at the junction of the N-type photodiode and the P-type photodiode when a bias voltage is applied.

11. A method comprising:
forming a P-type photodiode in a P-type semiconductor substrate; and
forming an N-type photodiode in the P-type semiconductor substrate over the P-type photodiode, wherein:
the junction of the P-type photodiode and the N-type photodiode form a depletion region, and
a depth of the depletion region configures the N-type photodiode to have a photoelectric effect in response to blue light.

12. The method of claim 11, wherein the method is a method of forming a CMOS image sensor.

13. The method of claim 11, wherein the P-type photodiode has a higher impurity concentration than the P-type semiconductor substrate.

14. The method of claim 1, wherein the depth of the depletion region substantially prevents a photoelectric effect in response to light having a wavelength greater than the wavelength of blue light.

15. The method of claim 11, wherein the depth of the depletion region is based on a depth of the N-type photodiode.

16. The method of claim 15, wherein the depth of the N-type photodiode is between approximately 0.1 μm and approximately 0.2 μm from the surface of the semiconductor substrate.

17. The method of claim 16, wherein the depth of the N-type photodiode is approximately 0.15 μm from the surface of the semiconductor substrate.

18. The method of claim 11, wherein said forming the P-type photodiode comprises implanting at least one of boron ions and BF4 ions.

19. The method claim 11, wherein said forming the N-type photodiode comprises implanting phosphorus ions.

20. The method of claim 11, wherein the depletion region is at the junction of the N-type photodiode and the P-type photodiode when a bias voltage is applied.
